(19) United States
(12) Patent Application Publication
(10) Pub. No.: US 2021/0314072 A1
(43) Pub. Date: Oct. 7, 2021

(54) DIGITAL PREDISTORTION VERIFICATION AND TX NONLINEARITY ESTIMATION

(71) Applicant: Avago Technologies International Sales Pte. Limited, Singapore (SG)

(72) Inventors: Dmitriy ROZENBLIT, Irvine, CA (US); Vincent Yves Francois ROUSSEL, Irvine, CA (US)

(21) Appl. No.: 16/838,946

(22) Filed: Apr. 2, 2020

(51) Int. Cl. H04B 15/06; H04B 1/04; H04B 17/13; H04B 17/10

(52) U.S. Cl. CPC H04B 15/06; H04B 1/0475; H04B 2001/0416; H04B 17/101; H04B 17/13

(57) ABSTRACT

A digital predistortion (DPD) verification and transmitter nonlinearity estimation system includes a transmitter path including one or more power amplifiers (PAs) coupled to an upconversion mixer. A digital tone generator circuit generates a single-tone radio-frequency (RF) signal that is applied to a first input of the upconversion mixer to generate a dual-tone RF signal, where a second input of the upconversion mixer is disabled. A downconversion mixer downconverts an amplified dual-tone RF signal to generate an intermediate-frequency (IF) dual-tone signal. A processing block analyzes the IF dual-tone signal to estimate signal strengths of one or more intermodulation (IM) product signals.

### TECHNICAL FIELD

The present description relates in general to wireless communication systems, digital predistortion verification and transmitter (TX) nonlinearity estimation.

### BACKGROUND

Transmitter (TX) nonlinearity is one of the most challenging issues in wireless communication. To improve nonlinearity, various techniques are employed, which may require additional hardware and calibration time and increased system complexity. Nevertheless, in spite of applied compensations, in most cases the actual improvement remains uncertain and often is based on statistical lab observations during development. Digital predistortion (DPD) may be used to improve overall TX linearity with respect to both spectrum and error-vector magnitude (EVM). This can be a fairly complex routine that permits attaining required performance at lower power consumptions, and, in some cases, this performance would not be attainable otherwise. The main issue with such an approach is that after the DPD calibration it is not known whether the output signal's distortion improved. Thus, there is always a possibility that in some rare cases an erroneous DPD calibration may actually cause additional distortions rather than an expected improvement. Unfortunately, in view of the required level of nonlinearity estimation, the complexity of the hardware and implementation cost, due to larger area and power consumption and/or supporting software, can be prohibitively high.

The same is true for performance optimization during development. For example, during the development phases, a bias current is tuned in the laboratory and the optimal settings based on statistical data are applied during production. However, due to process variations or variation in the performance of the external components, somewhat different optimal settings may be required. Therefore, the TX chain needs to be designed and/or optimized with larger initial margins to guarantee that unacceptable performance variation in the final product will not take place.

### BRIEF DESCRIPTION OF THE DRAWINGS

Certain features of the subject technology are set forth in the appended claims. However, for purposes of explanation, several embodiments of the subject technology are set forth in the following figures.

FIG. 1 illustrates an example of a digital predistortion (DPD) verification and transmitter (TX) nonlinearity estimation system, in accordance with one or more implementations of the subject technology.

FIG. 2 illustrates a chart showing plots of frequency spectra at various control nodes of the system of FIG. 1, in accordance with one or more implementations of the subject technology.

FIG. 3 illustrates an example of a digital processing block of the system of FIG. 1, in accordance with one or more implementations of the subject technology.

FIG. 4 illustrates a table showing a comparison between IM signals estimated via the system of FIG. 1 and an external spectrum analyzer.

FIG. 5 is a flow diagram illustrating an example of a method of DPD verification and TX nonlinearity estimation, in accordance with one or more implementations of the subject technology.

FIG. 6 is a block diagram illustrating a wireless communication device, within which one or more aspects of the subject technology can be implemented.

### DETAILED DESCRIPTION

The detailed description set forth below is intended as a description of various configurations of the subject technology and is not intended to represent the only configurations in which the subject technology may be practiced. The appended drawings are incorporated herein and constitute part of the detailed description, which includes specific details for providing a thorough understanding of the subject technology. However, the subject technology is not limited to the specific details set forth herein and may be practiced without one or more of the specific details. In some instances, structures and components are shown in a block-diagram form in order to avoid obscuring the concepts of the subject technology.

The subject technology relates to methods and systems for estimating an intermodulation (IM) product (IMx) before and after the digital predistortion (DPD) calibration (correction) as to verify the effectiveness of the DPD calibration. The main target for DPD calibration is an IM product, as well as some moderate phase shift as a function of a signal envelope (usually a secondary contributor). The subject disclosure estimates the IMx (x being 2, 3, 4, 5 etc.) products and utilizes them as the DPD verification tool or a tool to tune bias of the analog stages to reduce the IMx products.

The subject technology estimates IMx products (e.g., IM3) based on a dual-tone signal rather than based on an analysis of a complex spectrum. Moreover, estimating a level of a fixed known tone rather than a complex spectrum allows a simple solution that is more accurate and less expensive to implement. The transmitter (TX) linearity estimation is a useful tool and can be implemented in an inexpensive way using hardware along with a supporting algorithm. The subject technology can be used in any radio-frequency (RF) TX systems where linearity is critical. Existing solutions use a spectrum analyzer in production and rely on statistical data to assess the performance. An alternative existing solution is based on a dedicated measurement receiver that is costly and has a fairly high complexity. The disclosed solution is self-contained and inexpensive and can be routinely rerun during a product's operation to correct and/or validate performance over changing operating conditions (e.g., temperature, supply voltage and other conditions).

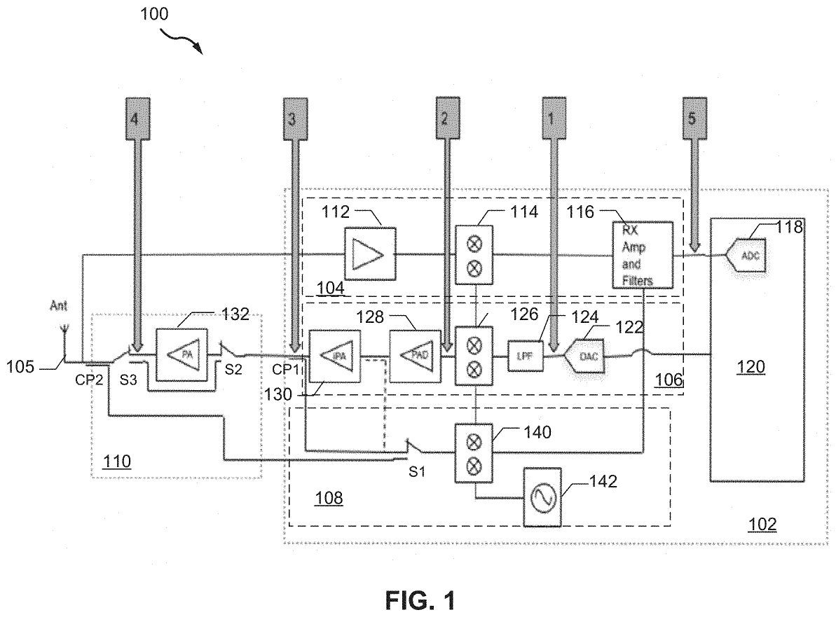

FIG. 1 illustrates an example of a DPD verification and TX nonlinearity estimation system 100, in accordance with one or more implementations of the subject technology. The DPD verification and TX nonlinearity estimation system 100 (hereinafter, system 100) includes an integrated circuit (IC) 102 and an external circuit 110. The IC 102 is a transceiver circuit including a receiver 104, a transmitter 106 and an auxiliary (Aux) receive (Rx) feedback chain 102 (hereinafter, Aux Rx chain 102). The receiver 104 includes a low-noise amplifier (LNA) 112, a downconversion mixer 114 and an Rx amplifiers and filters circuit 116, which may include one or two amplifier stages and band-pass filters. The transmitter 106 includes a digital-to analog converter (DAC) 122, a low-pass filter (LPF) 124, an upconversion mixer 126, a power amplifier driver (PAD) 128, a power amplifier (PA) 130 designated as iPA to indicate that it is an internal (to the IC 102) PA and a switch S1. The Aux Rx chain 108 includes a coupler CP1, a downconversion mixer 140 and a local oscillator (LO) 142.

The external circuit 110 includes switches S2 and S3, coupler CP2 and an external PA 132, which can be coupled to an antenna 105 via the switch S3. The switches S2 and S3 allow bypassing the external PA 132 when not needed. In some implementations, each of the PA 130 and the external PA 132 may include more than one amplification (gain) stages.

The PA 130 and the external PA 132 may have nonlinearities that have to be corrected via a predistortion circuit. There are many ways of specifying the linearity of a power amplifier, including P1 dB, intermodulation distortion (IMD) and noise power ratio (NPR). Predistortion calibration (correction) can be implemented in an analog as well as digital manner. The subject technology is focused on verification techniques for DPD calibration and uses a dual-tone RF signal in the transmitter path and measures respective IM products, as discussed herein.

To generate the dual-tone RF signal, the subject technology simply generates a digital single-tone baseband (BB) signal and feeds the single-tone signal at a control node 1 through the LPF 124 into the upconversion mixer 126. The upconversion mixer 126 is a complex frequency upconverter (modem), an inphase (I) or a quadrature (Q) arm of which is disabled prior to upconversion. This results in a quite balanced dual-tone RF signal at the output of an I/Q modulator with a suppressed LO feedthrough (due to the nature of the balanced TX mixers). Generation of the single-tone BB signal from a modem allows flexibility in a frequency separation selection. In one or more implementations, the frequency separation between the two tones of the dual-tone RF signal is twice the frequency of the single-tone BB signal. Because the frequency separation between the two tones of the dual-tone RF signal is known, all intermodulation products (in terms of their frequencies and other properties) are known as well. The peak signal power of the generated dual-tone RF signal has to be the same as a peak power during the DPD calibration. No analog settings are permitted to change between DPD calibration and verification stages.

The disclosed DPD verification technique reuses the entire Aux Rx chain 108 that is also used for DPD calibration. Therefore, the overall block diagram of the verification system of the subject technology looks quite similar to a DPD calibration block diagram. Also, the LO 142 of the downconversion mixer 140 of the Aux Rx chain 108 is used as the TX LO for the upconversion mixer 126 and the Rx LO for the downconversion mixer 114. This reduces the chance of having any additional IM products resulting from intermodulation and/or frequency beats between Rx LO and TX LO frequencies.

As noted above, the single-tone BB signal is interjected at the control node 1, before the LPF 124. The LPF 124 removes noise from the single-tone BB signal before up conversion by the upconversion mixer 126, which is a balanced mixer and generates the dual-tone RF signal. In some implementations, instead of the single-tone BB signal, a dual-tone BB signal may be used, in which case both I and Q arms of the upconversion mixer 126 are active. In this configuration, the upconversion mixer 126 may need to be balanced prior to utilization to prevent residual I/Q imbalance products from impacting the final IMx estimation.

The PAD 128 and PA 130 amplify the dual-tone RF signal. If the external PA 132 is not used, the switch S1 connects the downconversion mixer 140 to the coupler CP1 that provides a portion of the signal at the output of the PA 130 to the downconversion mixer 140. However, if the external PA 132 is also used, the switch S1 connects the downconversion mixer 140 to the coupler CP2, which provides a portion of the signal at the output of the external PA 132 to the downconversion mixer 140. The downconversion mixer 140 down converts the amplified dual-tone RF signal and feeds the resulting signal to the Rx amplifiers and filters circuit 116 to be filtered and delivered to an analog-to-digital converter (ADC) 118 of the digital processing block 120. The digital processing block 120 processes the digital signal provided by the ADC 118 to derive IM products, including the IM3 products, as described in more detail below.

In some implementations, when the external PA 132 is used, the receiver 104 may be used to down convert the amplified dual-tone RF signal instead of the downconversion mixer 140 of the Aux Rx channel 108. In one or more implementations, to improve flexibility (e.g., more bandwidth options), the subject technology utilizes digital transmitter-signal-strength indicator (TSSI) hardware to calculate the level of the downconverted tone, instead of reusing the DPD path. In some implementations, the TSSI hardware can be realized as a power detector-based subsystem. A feedback RX could be used as well in this role, although, typically, the detector-based subsystem consumes less power than the feedback RX, and therefore is more commonly used to set TX power to the required target.

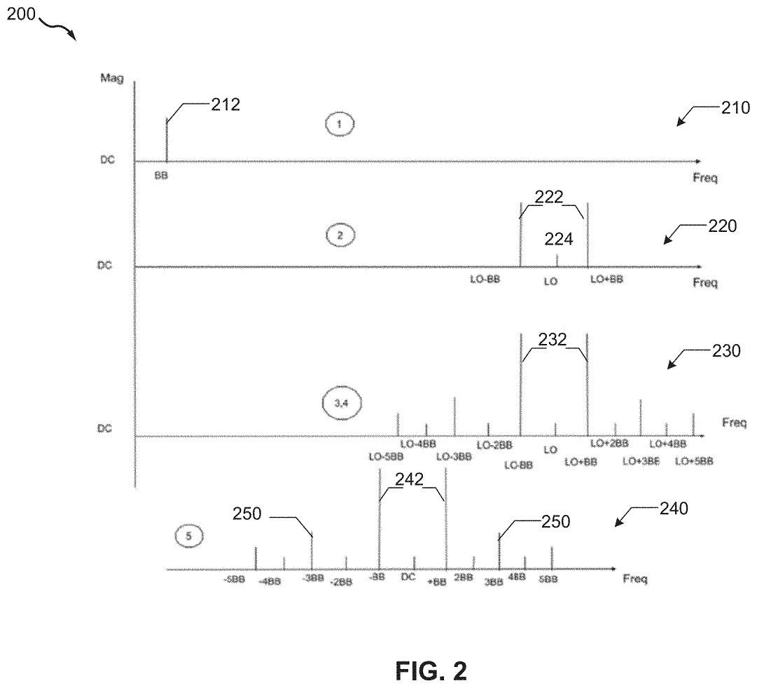

FIG. 2 illustrates a chart 200 showing plots 210, 220, 230 and 240 of frequency spectra at various control nodes of the system of FIG. 1, in accordance with one or more implementations of the subject technology. The plot 210 depicts the single-tone BB signal 212 at a BB frequency that is fed to the system 100 of FIG. 1 at the control node 1. The plot 220 depicts the double-tone RF signal 222 at a control node 2 of the system 100. The frequency separation between the two tones of the double-tone RF signal 222 is twice the BB frequency. The plot 230 depicts the RF signal at the control node 3 of the system 100. This RF signal results from amplification of the double-tone RF signal 222 by the PAD 128 and PA 130 of FIG. 1 and includes an amplified version (232) of the double-tone RF signal 222, as well as a number of IMx products due to the nonlinearity of the PA 130. The plot 240 depicts the spectrum of signals at the control node 5 of FIG. 1 and includes the dual-tone intermediate-frequency (IF) signal 242, and among other IM products, the IM3 products 250. The dual-tone IF signal 242 is a down converted version of the dual-tone RF signal 232 (by the down-converter 140 of FIG. 1) that is passed through the filtration by the Rx amplifiers and filters circuit 116 of FIG. 1.

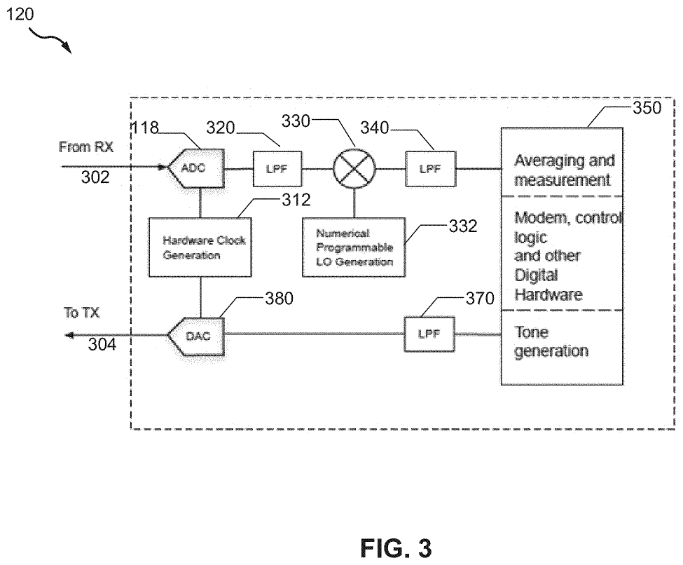

FIG. 3 illustrates an example of a digital processing block 120 of the system of FIG. 1, in accordance with one or more implementations of the subject technology. The digital processing block 120 receives an analog IF signal 302 from the receiver 104 of FIG. 1 and provides an analog BB tone 304 to the transmitter 106 of FIG. 1. The digital processing block 120 includes an RX path and a TX path. The RX path includes the ADC 118, a digital LPF 320, a digital mixer 330, a numerical programmable LO generator 332 and a digital LPF 340. The ADC 118 converts the analog IF signal 302 into a digital IF signal that is filtered by the digital LPF 320 and downconverted by the digital mixer 330 to a DC component to be further filtered by the digital LPF 340 and passed to the processor 350.

The processor 350 includes modem and control logic and digital hardware and can perform averaging and measurement of the IM products, including IM3 products. The processor 350 is further capable of tone generation and can produce a single-tone or dual-tone digital signal that is used by the TX path consisting of a digital LPF 370 and a DAC 380 that converts the filtered generated tones into the analog BB tone 304. The digital processing block 120 further includes a hardware clock generator 312 that provides clock signals for the ADC 118 and the DAC 380.

In some implementations, the digital mixer 330 can be implemented as a programmable coordinate-rotation digital computer (CORDIC) to rotate the frequency of the digitized IF signal 302 to a DC signal. This allows selection of the frequency component (e.g., main tone, IM product and so on) that will be processed by the processor 350.

The disclosed system measures a level of a narrow-band tone (IM product of choice), which allows achieving a much better resolution (to be able to estimate signals of very low levels) than is practically obtainable for a wide-band complex spectrum. The subject technology has the flexibility to average the interim results by the processor 350 and to change bandwidth of the digital LPFs (e.g., 320 and 340) used prior to recording the output (separate in I and Q). The processor 350 can calculate the total value of the measured product as a vector magnitude. The estimation solution of the subject technology is not limited to IM3 and can be used for various IM products. The maximum resolution of the subject estimation can be limited by a linearity of the downconversion mixer 140 of FIG. 1 on one hand and the noise floor of the downconversion mixer 140 plus the ADC 118 on the other hand. The maximum resolution could be somewhat improved by a longer averaging time of the measured output. An example, of the current estimation time for a single tone (e.g., IM product) is about 150 μs. A length of the measurement interval probably could be reduced, for example, to under 100 μs with more optimization of the bandwidth of the digital LPF and by changing the way output capture is activated. The verification tool of the subject technology can be used for BT TX in a production performance tuning regardless of the use or nonuse of the DPD calibration.

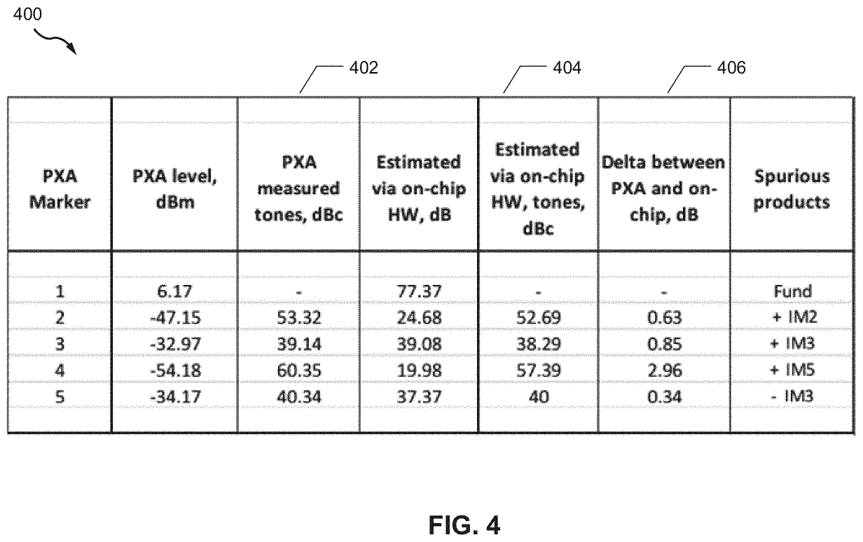

FIG. 4 illustrates a table 400 showing a comparison between IM signals estimated via the system of FIG. 1 and an external spectrum analyzer. The table 400, in rows 1 through 5, shows a number of measurement results of the fundamental component (Fund), +IM2, +IM3, +IM5 and −IM3 products. Only columns 402, 404 and 406 are of interest herein, showing values of the tones (in dBc) as measured by an external test equipment such as a spectrum analyzer (PXA), as estimated via on-chip hardware of the subject technology, and their differences, respectively. The difference results, shown in column 406, confirms that the on-chip IM estimation of the subject technology is reasonably accurate as compared with the test-equipment (PXA) results, and can be realized reusing already available hardware blocks and additional firmware support.

It should be noted that the existing solutions rely on a massive design-verification testing and automatic test equipment characterization to find these settings and assume that variations over process and temperature will not have a strong detrimental effect on the performance, which may or may not be accurate. Using the IM estimation tool of the subject technology, each part can be tuned to the best TX in-band spurious on a product level with a recheck over extreme temperatures. Because IM estimation time is relatively short, it should make it easier to schedule and execute.

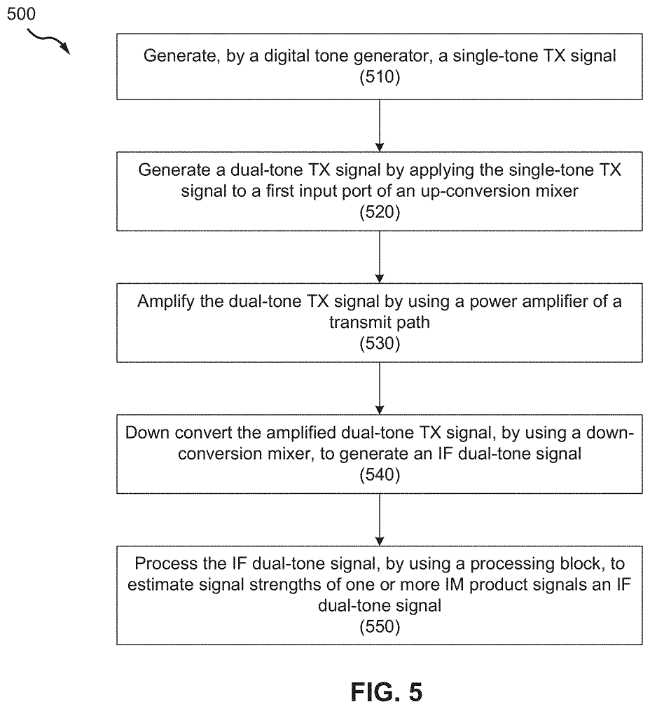

FIG. 5 is a flow diagram illustrating an example of a method 500 of DPD verification and TX nonlinearity estimation, in accordance with one or more implementations of the subject technology. The method 500 includes generating, via a digital tone generator (e.g., 250 of FIG. 2), a single-tone BB signal (e.g., 212 of FIG. 2) (510). The method 500 further includes generating a dual-tone RF signal (e.g., 222 of FIG. 2) by applying the single-tone BB signal to a first input port of an upconversion mixer (e.g., 126 of FIG. 1) (520). A second input of the upconversion mixer is disabled. The dual-tone RF signal is amplified by using a PA (e.g., 130 and or 132 of FIG. 1) of a transmit path (530). The amplified dual-tone RF signal (e.g., 230 of FIG. 2) is down converted, using a downconversion mixer (e.g., 140 of FIG. 1), to generate an IF dual-tone signal (e.g., 242 of FIG. 2) (540). The IF dual-tone signal is processed, by a digital processing block (e.g., 120 of FIG. 1 and FIG. 3), to estimate signal strengths of one or more IM product signals (e.g., 250 of FIG. 2) (550).

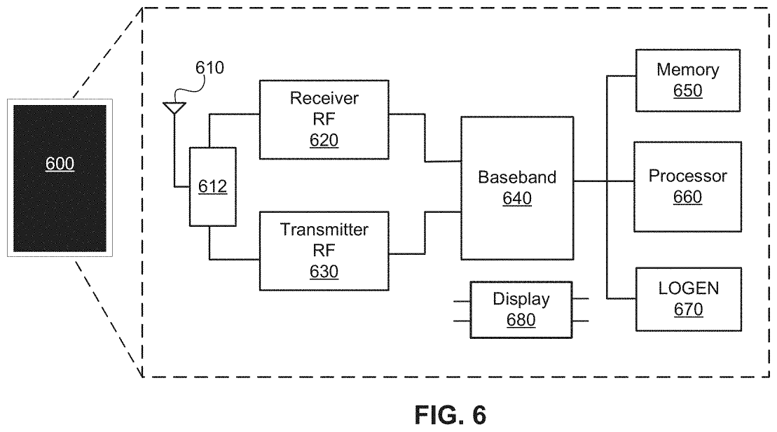

FIG. 6 is a block diagram illustrating a wireless communication device 600, within which one or more aspects of the subject technology can be implemented. In one or more implementations, the wireless communication device 600 can be a smartphone, a tablet, a laptop or any wireless mobile communication device. The wireless communication device 600 may comprise a RF antenna 610, a duplexer 612, a receiver 620, a transmitter 630, a BB-processing block 640, a memory 650, a processor 660, a LO generator (LOGEN) 670, and a display 680. In various embodiments of the subject technology, one or more of the blocks represented in FIG. 6 may be integrated on one or more semiconductor substrates. For example, the blocks 620-670 may be realized in a single chip or a single system on a chip, or may be realized in a multichip chipset.

The receiver 620 may comprise suitable logic circuitry and/or code that may be operable to receive and process signals from the RF antenna 610. The receiver 620 may, for example, be operable to amplify and/or downconvert received wireless signals. In various embodiments of the subject technology, the receiver 620 may be operable to cancel noise in received signals and may be linear over a wide range of frequencies. In this manner, the receiver 620 may be suitable for receiving signals in accordance with a variety of wireless standards, such as Wi-Fi, WiMAX, Bluetooth, and various cellular standards. In various embodiments of the subject technology, the receiver 620 may not use any saw-tooth acoustic wave filters and few or no off-chip discrete components such as large capacitors and inductors.

The transmitter 630 may comprise suitable logic circuitry and/or code that may be operable to process and transmit signals from the RF antenna 610. The transmitter 630 may, for example, be operable to upconvert BB signals to RF signals and amplify RF signals. In various embodiments of the subject technology, the transmitter 630 may be operable to upconvert and amplify BB signals processed in accordance with a variety of wireless standards. Examples of such standards may include Wi-Fi, WiMAX, Bluetooth, and various cellular standards. In various embodiments of the subject technology, the transmitter 630 may be operable to provide signals for further amplification by one or more PAs. The transmitter 630 may use DPD to correct nonlinearities of the one or more PAs and the DPD verification and TX nonlinearity estimation system of the subject technology to improve signal quality of the PAs.

The duplexer 612 may provide isolation in the transmit band to avoid saturating the receiver 620 or damaging parts of the receiver 620, and to relax one or more design requirements of the receiver 620. Furthermore, the duplexer 612 may attenuate the noise in the receive band. The duplexer 612 may be operable in multiple frequency bands of various wireless standards.

The baseband-processing block 640 may comprise suitable logic, circuitry, interfaces, and/or code that may be operable to perform processing of baseband signals. The baseband-processing block 640 may, for example, analyze received signals and generate control and/or feedback signals for configuring various components of the wireless communication device 600, such as the receiver 620. The baseband-processing block 640 may be operable to encode, decode, transcode, modulate, demodulate, encrypt, decrypt, scramble, descramble, and/or otherwise process data in accordance with one or more wireless standards. In one or more implementations, the baseband-processing block 640 may perform the functionalities of the digital processing block of FIG. 3.

The processor 660 may comprise suitable logic, circuitry, and/or code that may enable processing data and/or controlling operations of the wireless communication device 600. In this regard, the processor 660 may be enabled to provide control signals to various other portions of the wireless communication device 600. The processor 660 may also control the transfer of data between or among various portions of the wireless communication device 600. Additionally, the processor 660 may enable implementation of an operating system or otherwise execute code to manage the operations of the wireless communication device 600. In one or more implementations, the processor 660 may perform some of the functionalities of the digital processing block 120 of FIG. 1.

The memory 650 may comprise suitable logic, circuitry, and/or code that may enable storage of various types of information such as received data, generated data, code, and/or configuration information. The memory 650 may comprise, for example, RAM, ROM, flash, and/or magnetic storage. In various embodiments of the subject technology, information stored in the memory 650 may be utilized for configuring the receiver 620 and/or the baseband-processing block 640. In some implementations, the memory 650 may store image information from processed and/or unprocessed fingerprint images of the under-display fingerprint-sensing device of the subject technology. The memory 650 may also include one or more databases of reference fingerprints that can be used to identify and/or authenticate a person associated with the fingerprint.

The LOGEN 670 may comprise suitable logic, circuitry, interfaces, and/or code that may be operable to generate one or more oscillating signals of one or more frequencies. The LOGEN 670 may be operable to generate digital and/or analog signals. In this manner, the LOGEN 670 may be operable to generate one or more clock signals and/or sinusoidal signals. Characteristics of the oscillating signals such as the frequency and duty cycle may be determined based on one or more control signals from, for example, the processor 660 and/or the baseband-processing block 640.

In operation, the processor 660 may configure the various components of the wireless communication device 600 based on a wireless standard according to which it is desired to receive signals. Wireless signals may be received via the RF antenna 610, amplified, and downconverted by the receiver 620. The baseband-processing block 640 may perform noise estimation and/or noise cancellation, decoding, and/or demodulation of the baseband signals. In this manner, information in the received signal may be recovered and utilized appropriately. For example, the information may be audio and/or video to be presented to a user of the wireless communication device 600, data to be stored to the memory 650, and/or information affecting and/or enabling operation of the wireless communication device 600. The baseband-processing block 640 may modulate, encode, and perform other processing on audio, video, and/or control signals to be transmitted by the transmitter 630 in accordance with various wireless standards.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language claims, wherein reference to an element in the singular is not intended to mean “one and only one,” unless specifically so stated, but rather “one or more.” Unless specifically stated otherwise, the term “some” refers to “one or more”. Pronouns in the masculine (e.g., his) include the feminine and neuter gender (e.g., her and its) and vice versa. Headings and subheadings, if any, are used for convenience only and do not limit the subject disclosure.

The predicate words “configured to,” “operable to,” and “programmed to” do not imply any particular tangible or intangible modification of a subject, but rather are intended to be used interchangeably. For example, a processor configured to monitor and control an operation or a component may also mean the processor being programmed to monitor and control the operation or the processor being operable to monitor and control the operation. Likewise, a processor configured to execute code can be construed as a processor programmed to execute code or operable to execute code.

A phrase such as “an aspect” does not imply that such aspect is essential to the subject technology or that such aspect applies to all configurations of the subject technology. A disclosure relating to an aspect may apply to all configurations or one or more configurations. A phrase such as “an aspect” may refer to one or more aspects and vice versa. A phrase such as “a configuration” does not imply that such configuration is essential to the subject technology or that such configuration applies to all configurations of the subject technology. A disclosure relating to “a configuration” may apply to all configurations, or one or more configurations. A phrase such as a configuration may refer to one or more configurations and vice versa.

The word “example” is used herein to mean “serving as an example or illustration.” Any aspect or design described herein as “an example” is not necessarily to be construed as preferred or advantageous over other aspects or designs.

All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for.” Furthermore, to the extent that the terms “include,” “have,” or the like are used in the description or the claims, such terms are intended to be inclusive in a manner similar to the term “comprise,” as “comprise” is interpreted when employed as a transitional word in a claim.

Those of skill in the art would appreciate that the various illustrative blocks, modules, elements, components, methods and algorithms described herein may be implemented as electronic hardware, computer software, or combinations of both. To illustrate this interchangeability of hardware and software, various illustrative blocks, modules, elements, components, methods and algorithms have been described above generally in terms of their functionality. Whether such functionality is implemented as hardware or software depends upon the particular application and design constraints imposed on the overall system. Skilled artisans may implement the described functionality in varying ways for each particular application. Various components and blocks may be arranged differently (e.g., arranged in a different order, or partitioned in a different way), all without departing from the scope of the subject technology.

1. A digital predistortion (DPD) verification and transmitter (TX) nonlinearity estimation system, the system comprising:
a transmitter path including one or more power amplifiers (PAs) coupled to an upconversion mixer;
a digital tone generator circuit configured to generate a single-tone baseband (BB) signal that is applied to a first input port of the upconversion mixer for upconverting the single-tone BB signal to generate a dual-tone radio-frequency (RF) signal;
a downconversion mixer configured to downconvert an amplified dual-tone RF signal to generate an intermediate-frequency (IF) dual-tone signal; and
a processing block configured to process the IF dual-tone signal to estimate signal strengths of one or more intermodulation (IM) product signals,
wherein a second input port of the upconversion mixer is disabled prior to upconverting.

2. The system of claim 1, wherein the downconversion mixer belongs to a receive (RX) path of a transceiver, and wherein the amplified dual-tone RF signal is derived from an output of an external PA of the one or more PAs.

3. The system of claim 1, wherein the downconversion mixer belongs to an auxiliary RX path and the amplified dual-tone RF signal is derived from an output of an internal PA of the one or more PAs.

4. The system of claim 3, wherein the auxiliary RX path comprises an auxiliary feedback chain and includes a band-pass filter (BPF) and an analog-to-digital converter (ADC) that are reused for DPD verification and TX nonlinearity estimation.

5. The system of claim 1, wherein the processing block is implemented in hardware or partially in firmware, and wherein the processing block is configured to digitally downconvert the IF dual-tone signal and to compare values of multiple IM products estimated, respectively associated with before and after performing a DPD calibration, to verify an effectiveness of the performed DPD calibration.

6. The system of claim 1, and wherein the single-tone BB signal comprises a BB signal, wherein a frequency separation of two tones of the dual-tone RF signal is selectable, and wherein the frequency separation of two tones of the dual-tone RF signal is approximately equal to a frequency of a first tone of the dual-tone RF signal.

7. The system of claim 1, wherein a peak power of the dual-tone RF signal is approximately equal to a peak power signal during DPD calibration.

8. The system of claim 1, further comprising digital transmitter-signal strength indicator (TSSI) hardware configured to determine a level of the IF dual-tone signal.

9. The system of claim 1, wherein the processing block includes a programmable coordinate-rotation digital computer (CORDIC) to rotate a frequency of the IF dual-tone signal to select a desired IM product or a main tone.

10. The system of claim 1, wherein the upconversion mixer and the downconversion mixer are configured to use a same local oscillator (LO) signal to prevent creation of additional products by IM and/or frequency beats of two different LO signals.

11. A method of DPD verification and TX nonlinearity estimation, the method comprising:
generating, by a digital tone generator, a single-tone BB signal;
upconverting the single-tone BB signal to generate a dual-tone RF signal by applying the single-tone BB signal to a first input port of an upconversion mixer, wherein a second input port of the upconversion mixer is disabled prior to upconverting;
amplifying the dual-tone RF signal by using a PA of a transmit path;
downconverting, by using a downconversion mixer, an amplified dual-tone RF signal to generate an IF dual-tone signal; and
processing, by using a processing block, the IF dual-tone signal to estimate signal strengths of one or more IM product signals.

12. The method of claim 11, further comprising comparing values of multiple IM products estimated, respectively associated with before and after performing a DPD calibration, to verify an effectiveness of the performed DPD calibration.

13. The method of claim 11, wherein two tones of the dual-tone RF signal have a selectable frequency separation, further comprising setting the selectable frequency separation of two tones of the dual-tone RF signal approximately equal to a frequency of a first tone of the dual-tone RF signal.

14. The method of claim 11, wherein amplifying the dual-tone RF signal enables a peak power of the dual-tone RF signal to become approximately equal to a peak power signal during a DPD calibration.

15. The method of claim 11, further comprising reusing a BPF and an ADC of an existing auxiliary RX feedback chain for DPD verification and TX nonlinearity estimation.

16. The method of claim 11, further comprising determining a level of the IF dual-tone signal by using digital TSSI hardware.

17. The method of claim 11, further comprising rotating a frequency of the IF dual-tone signal to select a desired IM product or a main tone by using a programmable CORDIC.

18. A communication device comprising:
a transmit path including an upconversion mixer and one or more PAs;
a DPD circuit configured to correct nonlinearities associated with the one or more PAs;
a DPD-verification circuit configured to verify that the nonlinearities associated with the one or more PAs are corrected to a desired level, the DPD-verification circuit comprising:
a digital tone generator circuit configured to generate a single-tone BB signal that is applied to a first input port of the upconversion mixer for upconverting the single-tone BB signal to generate a dual-tone RF signal;
a downconversion mixer configured to downconvert an amplified dual-tone RF signal to generate an IF dual-tone signal; and
a processing block configured to process the IF dual-tone signal to estimate signal strengths of one or more IM product signals,
wherein a second input port of the upconversion mixer is disabled prior to upconverting.

19. The communication device of claim 18, wherein the processing block is further configured to compare a first and a second IM product estimated, respectively associated with before and after performing a DPD calibration, to verify an effectiveness of the performed DPD calibration.

20. The communication device of claim 18, further comprising:
an auxiliary RX feedback chain including a BPF and an ADC that are reused for DPD verification and TX nonlinearity estimation; and
digital TSSI hardware configured to determine a level of the IF dual-tone signal.
